(19) United States
(12) Patent Application Publication
(10) Pub. No.: US 2024/0219460 A1
(43) Pub. Date: Jul. 4, 2024

(54) ENHANCED ELECTRON BEAM (E-BEAM) APPARATUS AND METHODOLOGY WITH NANO-SCALE E-BEAM PROBE TIPS FOR FAULT ISOLATION IN INTEGRATED CIRCUITS AND OTHER STRUCTURES

(71) Applicants: Xianghong TONG, Hillsboro, OR (US); Jennifer HUENING, Hillsboro, OR (US); Joshua KEVEK, Portland, OR (US); Kimberlee CELIO, Portland, OR (US); Tristan DEBORDE, Hillsboro, OR (US); Prasoon JOSHI, Hillsboro, OR (US); May Ling OH, Portland, OR (US); Hyuk Ju RYU, Hillsboro, OR (US); Mitchell SENGER, Portland, OR (US); Martin VON HAARTMAN, Portland, OR (US); Yunfei WANG, Hillsboro, OR (US); Shuai ZHAO, Beaverton, OR (US)

(72) Inventors: Xianghong TONG, Hillsboro, OR (US); Jennifer HUENING, Hillsboro, OR (US); Joshua KEVEK, Portland, OR (US); Kimberlee CELIO, Portland, OR (US); Tristan DEBORDE, Hillsboro, OR (US); Prasoon JOSHI, Hillsboro, OR (US); May Ling OH, Portland, OR (US); Hyuk Ju RYU, Hillsboro, OR (US); Mitchell SENGER, Portland, OR (US); Martin VON HAARTMAN, Portland, OR (US); Yunfei WANG, Hillsboro, OR (US); Shuai ZHAO, Beaverton, OR (US)

(21) Appl. No.: 18/090,415

(22) Filed: Dec. 28, 2022

(51) Int. Cl. G01R 31/307; G01R 31/311

(52) U.S. Cl. CPC G01R 31/307; G01R 31/311

(57) ABSTRACT

This disclosure describes systems, methods, and devices related to electron beam and nanoprobing techniques with probe tips for fault isolation in integrated circuits. A method may include generating a signal at a circuit device under test while a probe tip electrically interacts with a transistor of the circuit device under test; detecting, based on the signal and the laser at the transistor, an electrical output of the circuit device under test; and identifying, based on the electrical output, a location of a fault at the circuit device under test.

### TECHNICAL FIELD

This disclosure generally relates to devices, systems, and methods for fault isolation in integrated circuits and, more particularly, to using electron beam and nanoprobing for fault isolation in integrated circuits.

### BACKGROUND

Fault isolation and failure analysis are critical aspects of integrated circuit design validation and debugging. Electron beam probers were widely used in the semiconductor industry. Optical probers replaced the electron beam prober. However, the resolution of the optical tools may be insufficient, and new backside power delivery technology may block the path for conventional optical analysis.

### BRIEF DESCRIPTION OF THE DRAWINGS

FIG. 1 is a schematic of an example electron beam prober with an electron beam signal image mapping capability, according to some example embodiments of the present disclosure.

FIG. 2 is a schematic of an example electron beam prober with optical-electrical fault mapping capability, in accordance with one or more example embodiments of the present disclosure.

FIG. 3 illustrates example electron beam probe tip configurations, in accordance with one or more example embodiments of the present disclosure.

FIG. 4 illustrates example nanoprobing on an active circuit using the electron beam probe tip of FIG. 3, in accordance with one or more example embodiments of the present disclosure.

FIG. 5 illustrates an example frequency enhanced electro force microscopy, in accordance with one or more example embodiments of the present disclosure.

FIG. 6 illustrates an example lock-in conductive atomic force microscopy, in accordance with one or more example embodiments of the present disclosure.

FIG. 7 illustrates an example frequency enhanced magnetic force microscopy, in accordance with one or more example embodiments of the present disclosure.

FIG. 8 illustrates an example lock-in scanning thermal microscopy, in accordance with one or more example embodiments of the present disclosure.

FIG. 9 illustrates an example lock-in scanning Joule expansion microscopy, in accordance with one or more example embodiments of the present disclosure.

FIG. 10 illustrates an example use of an electron beam to locally heat a circuit device under test, in accordance with one or more example embodiments of the present disclosure.

FIG. 11 illustrates a flow diagram of an illustrative process for using an electron beam probe tip for testing a circuit device, in accordance with one or more example embodiments of the present disclosure.

FIG. 12 depicts a block diagram of an example machine upon which any of one or more techniques (e.g., methods) may be performed, in accordance with one or more example embodiments of the present disclosure.

### DETAILED DESCRIPTION

The following description and the drawings sufficiently illustrate specific embodiments to enable those skilled in the art to practice them. Other embodiments may incorporate structural, logical, electrical, process, algorithm, and other changes. Portions and features of some embodiments may be included in, or substituted for, those of other embodiments. Embodiments set forth in the claims encompass all available equivalents of those claims.

For integrated circuits, fault isolation (FI) and failure analysis (FA) are critical parts of 1) product design validation and debug, 2) process development, 3) production yield improvement, 4) reliability testing and 5) product certification and product reliability qualification (PRQ). The ability to identify and isolate the failing circuits and devices often defines the success or failure of a product launch. Fault isolation and design debug today rely heavily on the ability to collect state information directly from transistors or metal lines.

Currently this is achieved by using optical tools such as Laser Assisted Device Alternation (LADA), Thermal Induced Voltage Alteration (TIVA), Optical Beam Induced Resistance Change (OBIRCh), Laser Voltage Probe (LVP)/Laser Timing Module (LTM) to locate the failing devices or circuit. The resolution of the optical approach is limited by the optical system resolution in IR range where silicon is transparent since the signal needs to go through the silicon to reach the devices or come from the device to reach the imaging system. The state-of-the-art resolution of such optical systems is about 240 nm using a 3.0 N.A. solid immersion lens, and around 120 nm for VLP (visible laser probing) tools.

Electron beam (e-beam) probing had been widely used before the development of optical tools for fault isolation more than fifteen years ago. The e-beam probers were capable of imaging the device state using voltage contrast, measuring the voltage on the metal traces and obtaining waveforms on the signal lines, and offered adequate spatial resolution. The e-beam probers were mainly used for front side probing and the resolution in these previous tools was at best 100 nm. They were replaced by the optical techniques because the flip chip packaging technology that became widely used did not provide access to the metal lines that the previous generation of e-beam probers relied on for analysis.

Test vehicles may be used for early process and yield development, and may be designed to envelope short segments of the integrated circuit process flow for faster fabrication and information turns. Some existing FI techniques may have limitations in resolution and throughput time on structures manufactured in a segmented flow. To better serve the needs for state-of-the art process development, the enhanced solutions presented herein improve resolution by orders of magnitude and decrease the time per defect (e.g., from several hours to several minutes). The fast data turns enabled by the enhanced techniques herein are critical for PowerVia and RibbonFET technologies, for example.

Laser-based fault isolation techniques, which relied on the ability to shine light on transistors by taking advantage of the silicon carrier wafers transparency to chosen wavelengths, are no longer viable with the introduction of backside power delivery (PowerVia). With this process introduction, nontransparent metal layers are now in the way of previous techniques, resulting in a need to identify other methods to induce local device alteration.

In one or more embodiments, these alterations may be induced by locally heating the die using a focused electron beam incident on a thin deposited metal film.

With novel sample preparation and analysis methods coupled with modern SEM technology, high-resolution e-beams can now be proposed as a next-generation FI platform capability. The enhanced e-beam prober (EBP) may use new high-resolution SEMs and analyze the probed signal on active chips. It applies e-beam probing from either the backside (from the silicon side) or front side of the device or interconnects after special sample preparation that exposes the silicon fins or diffusion or metal interconnects.

In one or more embodiments, the present disclosure adds probe tips to an e-beam tool to extend the capabilities of EBP and improve fault isolation efficiency, and adds probe tips to other integrated circuit fault isolation tools. The probe tips combine the functionality of nanoprobing, near field optics, thermal sensing, and atomic force microscopy (AFM) with EBP. There are currently no commercial tools available for probing on active circuitry with the high resolution of a modern SEM. Some existing types of nanoprobers include in-chamber probers with multiple probe tips (e.g., up to eight tips) so sharp that they can land on individual transistors of a device under test. Current e-beam probing does not provide actual physical contact with the individual transistors of a device. Adding such nanoprobe tips to an e-beam prober provides enhanced fault detection, in particular, by allowing for physical contact with individual transistors of a device to facilitate capacitance mapping (e.g., with AFM techniques—atomic force microscopy), monitoring and injecting signals and heat, to individual transistors of the device under test, biasing of individual transistors of the device under test, and other physical probing at the local level. The probe tips may be coupled to a laser or a fiber optic, for example, and may have a sensor (e.g., a magnetic sensor for AFM techniques, a thermal sensor for thermal scanning techniques, etc.). The probe tips may be driven by piezoelectric components or the like.

In one or more embodiments, use of the enhanced e-beam probing may provide superior resolution compared to the optical tools currently in use. The state of art optical tools can offer ˜240 nm resolution. Future tools may offer ˜120 nm resolution but the wavelength of the light makes further spatial improvements much more difficult if not impossible. The current electron beam systems offer resolution 1-2 orders of magnitude better, around 1-10 nm, which allows for the detection of individual transistor device/fins. The capability to detect individual failing fins within the device is unprecedented in the industry, providing for a significant advantage and a valuable tool for process development. In addition, the new backside power delivery technology blocks the path for conventional optical analysis, the ability to collect signals from metal lines or structures provided by e-beam probing enables fault isolation and debug on chips using backside power delivery technology.

In one or more embodiments, adding probe tips to the EBP tool adds additional capability to measure and insert logic states and waveforms on internal circuitry of an active chip with the high resolution of a modern SEM tool. In addition, scanning a probe tip with a near-field optical laser adds beyond diffraction limit optical tool techniques (LADA, TIVA, OBIRCh, TADA) or a probe tip with thermal sensitive material adds thermal sensing techniques (lock-in thermography) with the high resolution of modern SEMs.

In one or more embodiments, EBP alone provides only one probe for analysis on the active circuitry (the SEM beam). Additional manual probe tips allow for the use of multiple probes for signal insertion and analysis. These probes can be used in combination with the e-beam probe for improved defect localization. The probes may be of a same type or different types, and may be used without a SEM probe in some configurations.

In one or more embodiments, due to device degradation mechanisms with the e-beam at high energies, the electron beam energies are limited when exposing the devices for e-beam waveform, electron beam device perturbation (EDP), and electron beam signal image mapping (ESIM) collection. For the techniques proposed herein with the addition of probe tips, the SEM can be used at low energies to provide the required high resolution for navigation, while the probe tip is used for high resolution signal insertion or collection.

In one or more embodiments, the enhanced e-beam probing herein is facilitated from either the backside (e.g., from the silicon side) or front side of the device or interconnects after special sample preparation that exposes the silicon fins or diffusion or metal interconnects. This invention extends the EBP capabilities and efficiency of defect localization. Probe tips are used with EBP active circuitry for several applications.

In one or more embodiments, the present disclosure combines EPB (e-beam probing) with electrical probe(s) to achieve several enhanced techniques: (1) The electrical probe tip(s) are used to monitor or inject signal on active circuitry, or for combining EBP with nanoprobing techniques. (2) The probe tip(s) are used to focus a laser and scan a region of interest for high resolution near field optical probing including LADA (laser assisted device alteration) and TADA (thermally assisted device alteration), as well as OBIRCh (optical beam induced resistance change) fault isolation techniques. (3) A probe tip made of thermally sensitive or magnetic material can be used as a sensor for high resolution lock-in thermography or magnetic/current mapping fault isolation. In the application of magnetic/current mapping the electron column map needs to be in low magnetic field state or using an electrostatic lens. The nanoprobing can be achieved by using a SEM based NanoProber or Atomic Force Prober inside the chamber.

In one or more embodiments, for electrical probing of active circuitry, an electrical probe tip can be used to directly inject a logic state or waveforms while the output is monitored at a downstream circuit node or by the tester. The probe tip can also be used to monitor the logic state or waveform of electrical circuit nodes. By placing the probe tip in the path of a faulty device or circuit node, the electrical output is used to isolate the failing location.

In one or more embodiments, nanoprobing techniques including EBIC (electron beam induced current), EBAC (electron beam absorbed current), and EBIRCh (electron beam induced resistance change) can be used to isolate the defective location on the signal node. The current signal from the e-beam can be either collected by package pins or by probe tips and amplified and synced with e-beam scanning to produce a current image. By combining the capability of e-beam probing to isolate the failing node on a powered chip with nanoprobing capability of isolating the location of the fail on the node, defects can be quickly identified without having to change tools. ELSI (e-beam logic state imaging) and DELSI (dynamic ELSI) also may be used with nanoprobing and SEM imaging according to the techniques herein.

In one or more embodiments, for near-field optical fault isolation, a probe tip can be used to focus a laser and scan a region of interest for high resolution near field optical probing including LADA (laser assisted device alteration) and TADA (thermal assisted device alteration). The probe tip with laser scans across the region of interest while a test pattern loops at the fail to pass boundary. As the tip scans across the region of interest, the laser creates election-hole pairs and/or a thermal effect. On sensitive devices the test output will shift when the electron beam (or laser) is scanned over the device. The test is synced with the beam location on the sample to isolate faulty devices with high spatial resolution. Alternatively, the electrical response downstream to the laser scanning can be monitored by e-beam analysis. Failures can be identified with changes in logic state and/or waveforms while the laser scans faulty devices. Alternatively other probe tips could be used to bias and detect the changes in the local circuit while the probe tip with laser scans across the region of interest.

In one or more embodiments, the near-field focused beam can also be used to create current maps as the laser scans across the surface for OBIRCh imaging. Similarity to EBIRCh, the current signal OBIRCh can be either collected by package pins or probe tip and amplified and synced with laser scanning to produce a current image.

In one or more embodiments, the e-beam probe may be used for thermal sensor lock-in thermography and magnetic sensor for magnetic field and current mapping. The probe tip can be made of thermally sensitive material or magnetically sensitive materials to be used as a thermal detector or magnetic field detector. As the probe tip scans across the surface, heat information or magnetic field/current is collected in a localized area. The lock-in technique is used to improve the thermal sensing sensitivity. Faulty devices with higher levels of heat dissipation can therefore be detected.

In one or more embodiments, automated enhanced techniques may include FE-EFM: Frequency enhanced electro force microscopy; FE-MFM: Frequency enhanced magnetic force microscopy; SJEM4FI: Scanning joule expansion microscopy for fault isolation; LI-SThM: Lock-in scanning thermal microscopy; SPADA: Scanning probe assisted device alteration; and LI-CAFM: Lock-in conductive AFM. Table 1 below summarizes improvements provided by the enhanced scanning probe techniques herein compared to other FI. These enhanced techniques may be used with the enhanced e-beam tool described herein, or outside of the e-beam tool. Each of the enhanced techniques may use the enhanced e-beam probe tip described herein, but do not have to use the e-beam probe tip.

TABLE 1
Summary of Improvements from Enhanced
Scanning Probe Techniques:

| Feature | Conventional | Scanning Probe FI | Enhancement |
|---|---|---|---|
| Resolution | 200 nm-1 um | 5-10 nm | 20-200x |
| Information turns | Full-loop | Quick turn monitor | Months faster |
| FI Time | 3-8 hours | 3-30 min | 6x-160x |
| Capability | Unit-level | Full-wafer | Enables full- |
| | | | wafer FA with |
| | | | automation |

In one or more embodiments, the enhanced techniques herein address multiple types of faults, including electrical shorts, electrical opens, logic fails, and parametric fails.

In one or more embodiments, enhanced FE-FEM allows for “maps” of an electric field to be generated by monitoring the oscillation of a cantilever probe. This oscillation is driven by the capacitive coupling between the probe and the sample. In order to enhance the signal to noise ratio, circuits may be driven at the resonance frequency of the cantilever. The throughput time and resolution may be aided by driving each side of our failing structure 180 degrees out of phase. This enables use of quadrature or in-phase images to determine which parts of the circuit are associated with each connection. Another advantage of this detection scheme is that it provides destructive interference at the fail boundary, giving a quick way for the user to see in what area the fail occurs.

In one or more embodiments, enhanced LI-CAFM allows for maps of the current flowing in and out of a scanning probe to be made when in contact with or otherwise electrically interacting with (e.g., from some non-zero distance) the enhanced device. Oscillating the voltages on a sample may allow for use a lock-in amplifier to enhance the signal-to-noise ratio (SNR). To enhance throughput, either a negative bias on one side and or a positive bias on the other side or 0 degree phase on one side and 180 degree phase on the other side may be applied. This technique enables resolution on the order of ˜10 nm. By using the e-beam probe tip, the enhanced LI-CAFM may allow direct contact between the probe tip and surface.

In one or more embodiments, electrical short fails may be defined by a low resistance measured between two metal lines of interest, typically in the 100 kilo-ohm range or below. Using FE-MFM, maps of the magnetic field may be generated by monitoring the oscillation of the cantilever probe. This oscillation is driven by the magnetic coupling between the probe and the sample. To enhance the signal-to-noise ratio, the circuit may be driven at the resonance frequency of a cantilever. Driving devices in this way may generate an oscillating current which in turn creates an oscillating magnetic field. The shorting defects may be found at an area of higher current density, and therefore there may be stronger coupling to the probe at that point. Instead of EFM, a magnetic coupling may be used.

In one or more embodiments, using enhanced LI-SThM, maps of the die surface temperature may be generated. The relative surface temperature of the defective area tends to be hotter than the surrounding area. This temperature can be measured by scanning the surface with a temperature sensitive resistor, for example. This change in resistance may be monitored (e.g., with a Wheatstone bridge). Oscillating the applied current on the failing device may allow for use a lock-in amplifier attached to the Wheatstone bridge to increase the SNR.

In one or more embodiments, using enhanced SJEM4FI, maps of the expansion and contraction of samples may be generated. This expansion and contraction may be driven by the local heating and cooling induced by the defect. By placing an ultra-sharp probe in hard contact with the surface, the probe may move up and down as the device heats and cools. To enhance the SNR, the clamped beam resonance of the AFM cantilever with a lock-in amplifier may be monitored, the structures may be driven at this frequency.

In one or more embodiments, using enhanced SPADA, maps of the probe's effect on circuit functionality may be generated. To affect the circuit functionality, an ultra-hot (e.g., ˜400 C) probe may be positioned in contact with the surface being sampled. The heating may affect the electrical behavior of the devices being tested. There are multiple ways of measuring the device changes. One method is to monitor the current change of the device. To do this, a small bias may be applied across the circuit, and then a map of that current value may be generated as the probe scans. In the area of the defect, a change in the current flowing through the device may be observable. Another method is to “loop” a test pattern into the device that may then be scored as a pass or a fail. By testing the device at various voltages, the boundary where the device fails may be identified. By operating our device at this boundary voltage and then scanning the device with the hot probe, the pass/fail condition at each pixel of the scan may be mapped. Defective areas will lead to a higher passing or failing rate relative to the non-defective area. SPADA is more sensitive to high-resistance situations.

In one or more embodiments, one or more nanoprobe tips or a tester may bias the circuit so that the electric field on some nodes inside the circuits toggle with a given frequency and duty cycle. By driving these structures so that the data toggles at the resonance frequency of the probe, an enhanced combination of EFM and MFM may be used to generate maps of the amplitude and phase of the electric/magnetic field. The signal propagation through these logic circuits is perturbed by the defect, which produces an electric and/or a magnetic field change that can be detected by the probe tip. By comparing this to a reference structure, information about the fail mode may be obtained.

In one or more embodiments, an ultra-high resolution hot spot generated via high current e-beam may be introduced to induce a change in measured circuits under test. Under certain conditions, a thin electron absorption layer may be added to the surface to aid the heating without device damage. In this manner, instead of using a hot AFM tip, the enhanced e-beam probe may be used instead. Compared to laser techniques, the e-beam may provide better penetration when testing a circuit for a fault.

In one or more embodiments, multiple probes may be used in combination with one another for fault isolation. The multiple probes may be of a same type or different types (e.g., a combination of different probes). The multiple probes each may have probe tips, and may not be limited to e-beam probes.

The above descriptions are for purposes of illustration and are not meant to be limiting. Numerous other examples, configurations, processes, algorithms, etc., may exist, some of which are described in greater detail below. Example embodiments will now be described with reference to the accompanying figures.

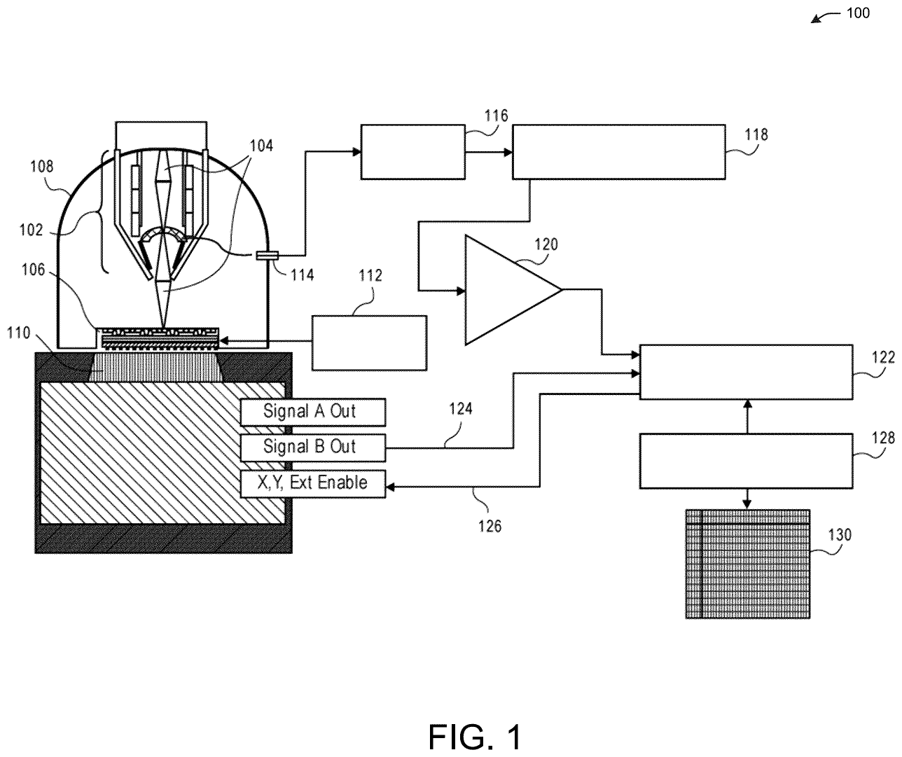

FIG. 1 is a schematic of an example electron beam prober 100 with an electron beam signal image mapping capability, according to some example embodiments of the present disclosure.

Referring to FIG. 1, the e-beam prober 100 includes an e-beam column 102 (such as a scanning electron microscope (SEM) column), for delivering a beam 104 to a device under test (DUT) 106. The e-beam column 102, or at least a portion of the e-beam column 102 may be housed in a chamber 108, and the device under test (DUT) 106 may be supported by a stage 110, as is depicted.

In the e-beam prober 100, a signal generator 112 is coupled to the DUT 106. A detector 114 which is in the path of beam 104 or by the side of the e-beam column 102 is coupled to a sensing module 116. The sensing module 116 is coupled to a lock-in amplifier or spectrum analyzer 118 which is coupled to an operation amplifier 120. A scan module 122 is coupled to the operation amplifier 120 and can receive Scanning Electron Microscope (SEM) image signal 124 or send external x-y scan control signals 126 to the control board of electron column 102. A computer controller 128 can produce scanning electron microscope (SEM) images or electron-beam signal image mapping (ESIM) images 130.

In an embodiment, using an ELSI approach, an e-beam logic state imaging technique allows detection and display of the logic state of integrated circuit structures or devices of interest. In an embodiment, one of two approaches is used to achieve detection of the logic state of the integrated circuit structures or devices. In a first ELSI approach, static e-beam logic state imaging (SELSI) is used. In a second ELSI approach, dynamic e-beam logic state imaging (DELSI) is used. It is to be appreciated that optical tools using a laser beam could be configured to provide logic state imaging on devices of interest but the resolution is an order of magnitude lower. Conventional e-beam probers do not offer dynamic logic state imaging.

In an embodiment, using the SELSI technique in an ELSI approach, the integrated circuit structure or device of interest is put in a specific state by halting a tester pattern. Biasing also may come from separate probe tips. A secondary electron image of the integrated circuit structures or devices is collected. The integrated circuit structures or devices show different contrast at high or low voltage states, allowing identification of the individual device logic states. In an embodiment, the SELSI approach is applicable for both P-type and N-type integrated circuit structures or devices. In an embodiment, images collected for conductive structures (e.g., interconnects on the front side) of devices toggled with different logic states may reveal the following: lower positive voltages show brighter contrast and higher positive voltages show darker contrast due to differing amounts of secondary electrons reaching the detector from the structures at different voltages.

In another embodiment, using the DELSI technique in an ELSI approach, an electron beam is scanned over an area containing the device of interest. Instead of gate modulation, Vcc power supply of the integrated circuit structures or devices of interest is modulated at a specific frequency. The secondary electron signal is amplified then sent to a lock-in amplifier or spectrum analyzer tuned to the specific frequency. The output of the lock-in amplifier or spectrum analyzer is fed into a scan control unit that monitors or drives the raster over the area. In an embodiment, a signal from the lock-in amplifier or spectrum analyzer is brighter than the rest of the area or areas scanned. Since the Vcc and/or signal is modulated, only the integrated circuit structure or device that is on (e.g., connected to Vcc) shows the modulation in the secondary electron detector. The result allows mapping of devices that are turned on, enabling mapping of the logic states. In an embodiment, one subtle effect is that in an inverter chain the Vcc and/or signal modulation can cause the output of the inverters to also modulate leading to modulation on the gate of the downstream inverter. In an embodiment, by comparing with a CAD layout and a test pattern defective integrated circuit structures or devices can be located and identifies as being in an incorrect logic state.

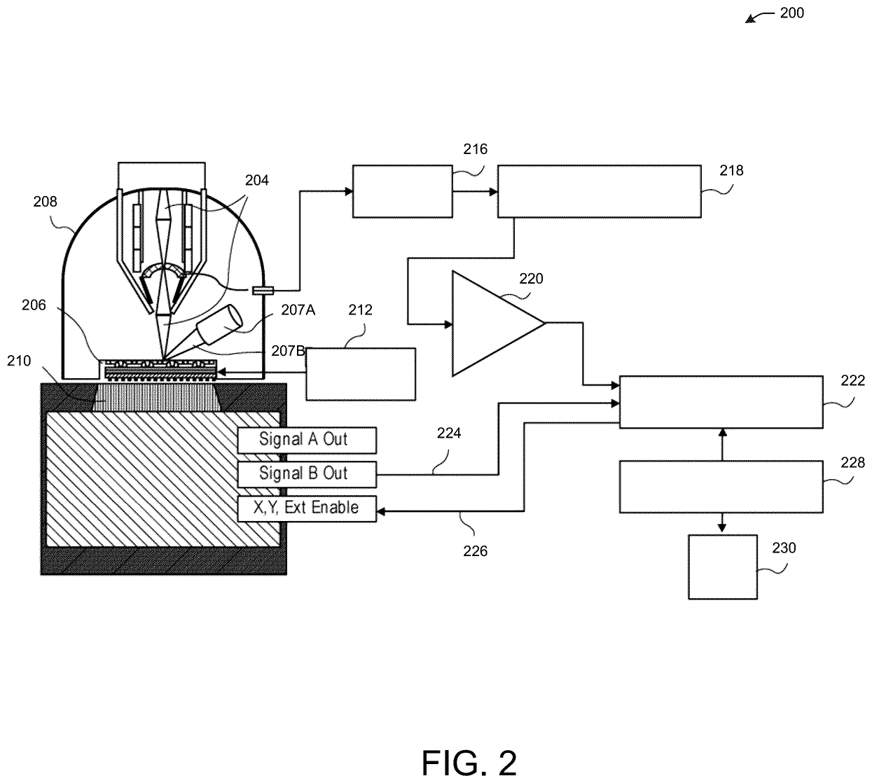

FIG. 2 is a schematic of an example electron beam prober 200 with optical-electrical fault mapping capability, in accordance with one or more example embodiments of the present disclosure.

Referring to FIG. 2, the e-beam prober 200 includes an e-beam column (such as a scanning electron microscope (SEM) column) for delivering a beam 204 to a device under test (DUT) 206. The e-beam column, or at least a portion of the e-beam column may be housed in a chamber 208, and the device under test (DUT) 206 may be supported by a stage 210, as is depicted. A laser source 207A is included together with the e-beam column in the e-beam prober 200. The laser source 207A is configured to output a laser beam 207B directed to the DUT 206, as is depicted.

In the e-beam prober 200, a signal generator 212 is coupled to the DUT 206. A detector 214 which is in the path of beam 204 is coupled to a sensing module 216. The sensing module 216 is coupled to a lock-in amplifier or spectrum analyzer 218 which is coupled to an operation amplifier 220. A scan module 222 is coupled to the operation amplifier 220 and can receive a Scanning Electron Microscope (SEM) image signal 224 or send external x-y scan control signals 226 to the control board of electron column 202. A computer controller 228 can produce scanning electron microscope (SEM) images or electron-beam signal image mapping (ESIM) images 230.

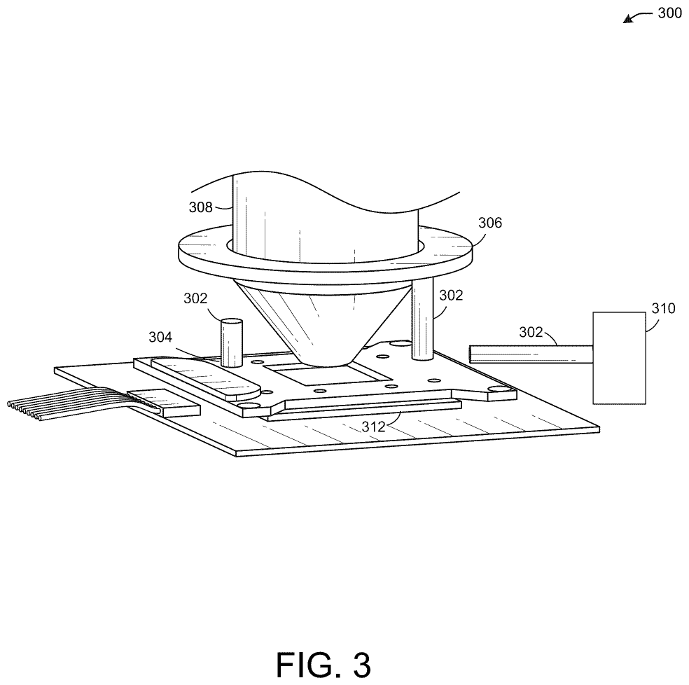

Referring to FIGS. 1 and 2, the emission of an e-beam may be used to detect changes in a device under test. By emitting the e-beam, the electron variations of the device under test may be used to determine a waveform of the device under test at a high resolution. The e-beam also may be used to detect where a signal in the device under test is present or not (e.g., where an open occurs and a signal is not present). The e-beam also may be used to detect shorts (e.g., where there is modulation and should not be). The e-beam probes of FIGS. 1 and 2 may be enhanced by adding probe tips using one or more of the configurations shown in FIG. 3.

FIG. 3 illustrates example electron beam probe tip configurations 300, in accordance with one or more example embodiments of the present disclosure.

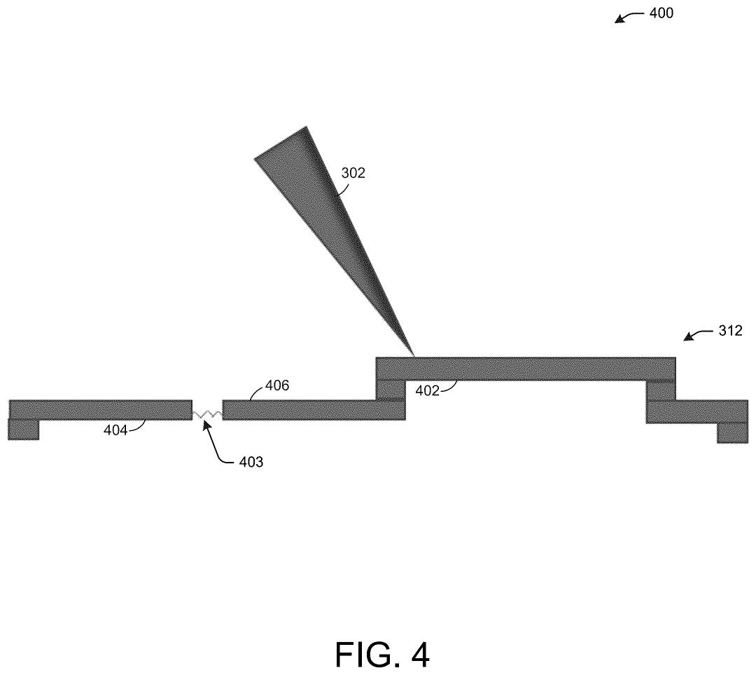

Referring to FIG. 3, the configurations 300 are exemplary and not meant to be limiting. As shown further in FIGS. 4-10, there are multiple FI techniques that can be used. The probe tip configurations 300 are example configurations that may be applied to the techniques in FIGS. 4-10, although other configurations for the probe tips may be used. The configurations 300 may be used together in combination (e.g., when multiple probe tips are implemented with a probing tool). In the example configurations 300 shown in FIG. 3, one configuration is to mount a probe tip 302 on a sample holder 304. Another configuration is to mount the probe tip 302 on a ring 306 around a pole piece 308 (e.g., of the e-beam column 102 of FIG. 1). Another configuration may be to mount the probe tip 302 (e.g., to a chamber sidewall or ceiling 310, e.g., of the chamber 108 of FIG. 1).

In one or more embodiments, a device under test 312 may be in contact with or otherwise electrically interacting with (e.g., from some non-zero distance) the probe tip 302, allowing for enhanced fault detection. The device under test 312 may be powered by the tester, and a signal may be induced at the device under test 312 or collected by the probe tip 302 using any one or more of the configurations 300. The probe tip 302 may be used to directly inject a logic state or waveform into the device under test 312, while the output of the device under test 312 may be monitored at a downstream circuit node or by the tester. The probe tip 302 may be used to monitor the logic state or waveform of individual circuit nodes of the device under test 312 (e.g., by being in contact with or otherwise electrically interacting with (e.g., from some non-zero distance) the individual circuit nodes).

FIG. 4 illustrates example nanoprobing on an active circuit using the electron beam probe tip 302 of FIG. 3, in accordance with one or more example embodiments of the present disclosure.

Referring to FIG. 3, the probe tip 302 may be in contact with or otherwise electrically interacting with (e.g., from some non-zero distance) a signal top metal line 402 (e.g., of the device under test 312 of FIG. 3). The probe tip 302 may measure a signal and may insert a signal for a test to pass. The probe tip 302 may be used to detect a resistive open 403 between metal lines 404 and 406 (e.g., causing a test to fail).

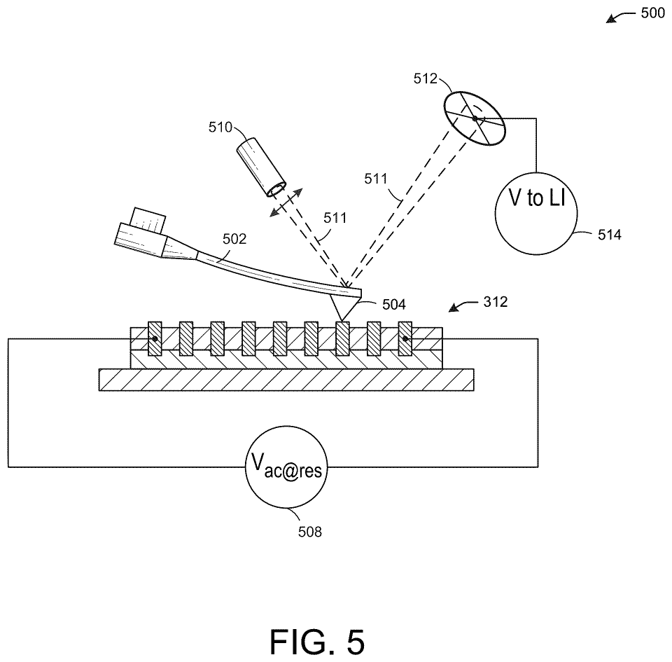

FIG. 5 illustrates an example FE-FEM 500, in accordance with one or more example embodiments of the present disclosure.

Referring to FIG. 5, a cantilever 502 with a probe 504 (e.g., having the probe tip 302 of FIG. 3 or not having the probe tip 302) may be in contact with or otherwise electrically interacting with (e.g., from some non-zero distance) the device under test 312 of FIG. 3. An AC bias voltage 508 may be applied to the device under test 312 for the probe 504 to sample at the cantilever 502 resonance (e.g., one side at 0 degrees phase, the other side of fail at 180 degrees phase). A laser diode 510 may emit a laser 511 at the probe 504 while in contact with or otherwise electrically interacting with (e.g., from some non-zero distance) the device under test 312, and a photodetector 512 may detect the reflected laser 511. The photodetector 512 output may be sent into lock-in 514 during float pass of the measurement. The tip resonance may be driven by a capacitive coupling to the sample.

With this technique in FIG. 5, maps of the electric field may be generated by monitoring the oscillation of the cantilever 502 probe 504. This oscillation is driven by the capacitive coupling between the probe 504 and the sample. In order to enhance the signal-to-noise ratio (SNR), the device under test 312 may be driven at the resonance frequency of the cantilever 502. In addition, the throughput time and resolution may be aided by driving each side of the failing structure 180 degrees out of phase, enabling use quadrature or in-phase images to determine which parts of the device under test 312 are associated with each connection. Another advantage of this detection scheme is that it provides destructive interference at the fail boundary giving a quick way for the user to identify which area the fail is in.

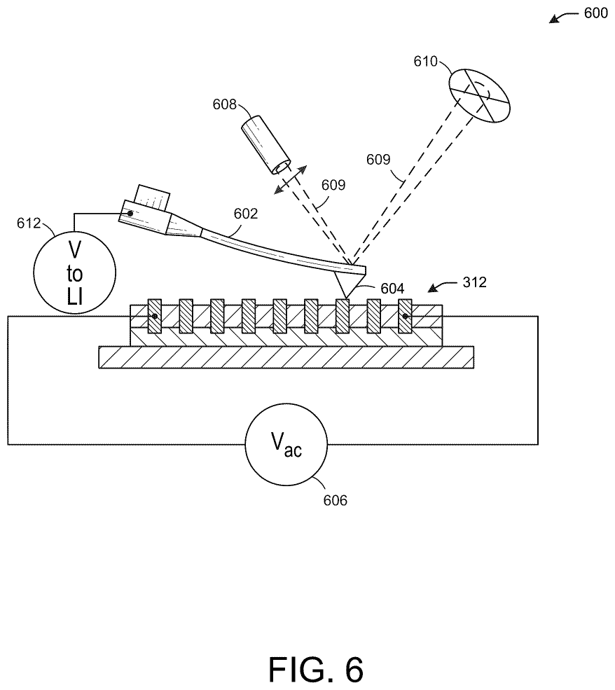

FIG. 6 illustrates an example LI-CAFM 600, in accordance with one or more example embodiments of the present disclosure.

Referring to FIG. 6, a cantilever 602 with a probe 604 (e.g., having the probe tip 302 of FIG. 3 or not having the probe tip 302) may be in contact with or otherwise electrically interacting with (e.g., from some non-zero distance) the device under test 312 of FIG. 3. An AC bias voltage 606 may be applied to the device under test 312 for the probe 604 to sample. A laser diode 608 may emit a laser 609 at the probe 604 while in contact with or otherwise electrically interacting with (e.g., from some non-zero distance) the device under test 312, and a photodetector 610 may detect the reflected laser 609. The voltage measured from tip of the probe 604 to surface of the device under test 312 may be measured and fed into a lock-in (LI) amplifier 612 of the cantilever 602.

With this technique in FIG. 6, maps of the current flowing in and out of the scanning probe 604 when in contact with or otherwise electrically interacting with (e.g., from some non-zero distance) the device under test 312 may be made. Oscillating the voltages allows for use of the LI amplifier 612 to enhance SNR. To enhance throughput, application of either a negative bias on one side and positive on the other or 0 deg phase on one side and 180 deg phase on the other may be used. This technique enables resolution on the order of ˜10 nm.

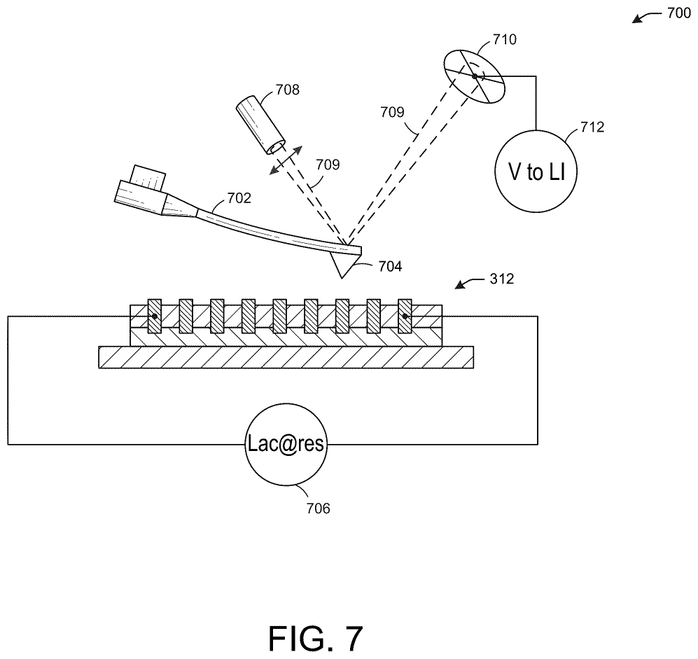

FIG. 7 illustrates an example FE-MFM 700, in accordance with one or more example embodiments of the present disclosure.

Referring to FIG. 7, a cantilever 702 with a probe 704 (e.g., having the probe tip 302 of FIG. 3 or not having the probe tip 302) may be in contact with or otherwise electrically interacting with (e.g., from some non-zero distance) the device under test 312 of FIG. 3. An AC current 706 may be applied to the device under test 312 for the probe 704 to sample at cantilever 702 resonance. A laser diode 708 may emit a laser 709 at the probe 704 while in contact with or otherwise electrically interacting with (e.g., from some non-zero distance) the device under test 312, and a photodetector 710 may detect the reflected laser 709. The photodetector 710 output may be sent into LI 712 during float pass of the measurement. The tip resonance may be driven by magnetic coupling of the sample.

With this technique of FIG. 7, maps of the magnetic field are generated by monitoring the oscillation of the cantilever 702 probe 704. This oscillation is driven by the magnetic coupling between the probe 704 and the sample (e.g., the device under test 312). In order to enhance signal to noise ratio, the device under test 312 may be driven at the resonance frequency of the cantilever 702. Driving devices in this way allows for generating the oscillating current 706, which in turn creates an oscillating magnetic field. Shorting defects are usually found at an area of higher current density, and therefore there is a stronger coupling to the probe 704 at that point.

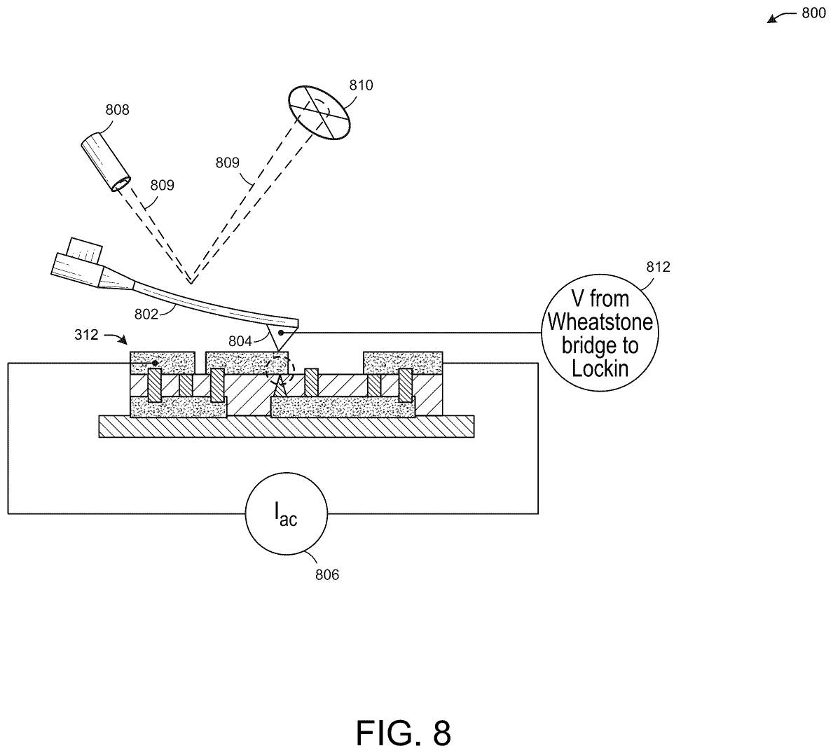

FIG. 8 illustrates an example LI-SThM 800, in accordance with one or more example embodiments of the present disclosure.

Referring to FIG. 8, a cantilever 802 with a probe 804 (e.g., having the probe tip 302 of FIG. 3 or not having the probe tip 302) may be in contact with or otherwise electrically interacting with (e.g., from some non-zero distance) the device under test 312 of FIG. 3. An AC current 806 may be applied to the device under test 312 for the probe 804 to sample. A laser diode 808 may emit a laser 809 at the probe 804 while in contact with or otherwise electrically interacting with (e.g., from some non-zero distance) the device under test 312, and a photodetector 810 may detect the reflected laser 809. The AC current 806 may flow through the device under test 312, and a defect may cause heating at the AC frequency, which changes the resistance of the probe 804. The output of a Wheatstone bridge may be fed into LI at 812.

With this technique of FIG. 8, maps of the die surface (e.g., of the device under test 312) temperature are made. The relative surface temperature of the defective area tends to be hotter than the surrounding area. This temperature is measured by scanning the surface with a temperature sensitive resistor (e.g., of the probe 804). This change in resistance is then monitored with the Wheatstone bridge 812. Oscillating the applied current on the failing device can allow for use a lock-in amplifier attached to the Wheatstone bridge 812 to increase SNR.

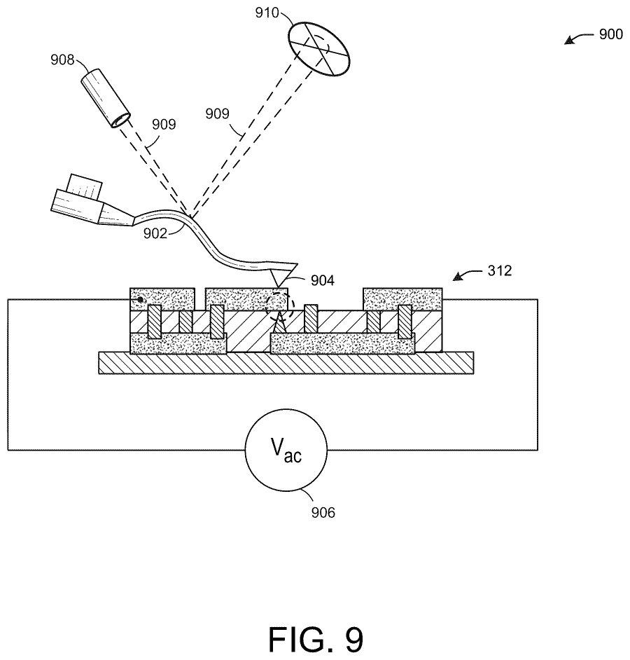

FIG. 9 illustrates an example SJEM4FI 900, in accordance with one or more example embodiments of the present disclosure.

Referring to FIG. 9, a cantilever 902 with a probe 904 (e.g., having the probe tip 302 of FIG. 3 or not having the probe tip 302) may be in contact with or otherwise electrically interacting with (e.g., from some non-zero distance) the device under test 312 of FIG. 3. An AC current 906 may be applied to the device under test 312 for the probe 904 to sample. A laser diode 908 may emit a laser 909 at the probe 904 while in contact with or otherwise electrically interacting with (e.g., from some non-zero distance) the device under test 312, and a photodetector 910 may detect the reflected laser 909. The AC current 906 may flow through the device under test 312, and may cause heating (e.g., thermal expansion) of the device under test 312 at the AC frequency, which may result in a change in the resistance of the probe 904 when the probe is electrically interacting with the device under test 312 (e.g., either in contact with or near the device under test 312).

With this technique of FIG. 9, maps of the expansion and contraction of the samples (e.g., of the device under test 312) are made. This expansion and contraction is driven by the local heating and cooling induced by the defect. By placing an ultra-sharp probe (e.g., the probe 904) in hard contact with the surface of the device under test 312, the probe 904 will move up and down as the device under test 312 heats and cools. To enhance SNR, a clamped beam resonance of the AFM cantilever 902 may be measured with a lock-in amplifier.

Referring to FIGS. 4-9, the FI detection techniques may not use e-beams, but e-beam probe tips may allow for improved detection and localization of the faults as described above.

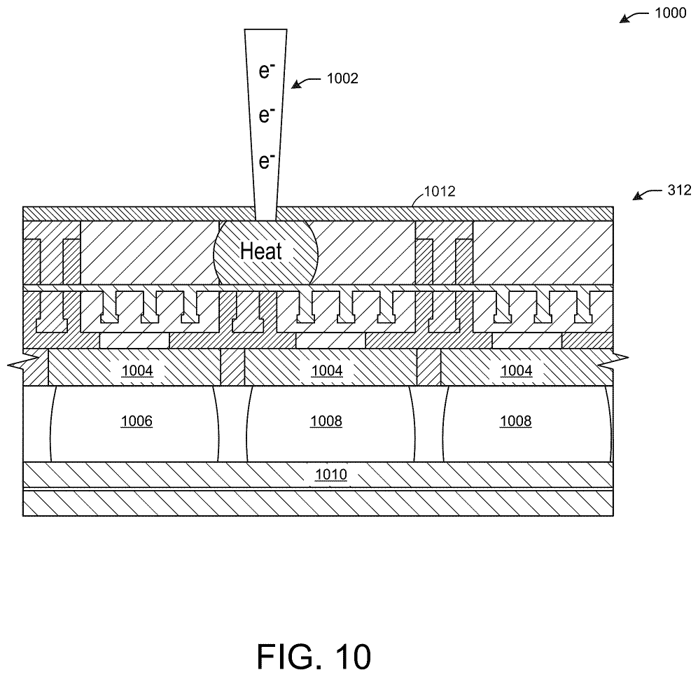

FIG. 10 illustrates an example use 1000 of an electron beam to locally heat a circuit device under test (e.g., the device under test 312 of FIG. 3), in accordance with one or more example embodiments of the present disclosure.

As shown in FIG. 10, ultra-high resolution heat generation via a high-current e-beam 1002 may be introduced to the device under test 312 to induce changes to the device under test 312. The induced changes to the device under test 312 as caused by the high-current e-beam 1002 may be measured (e.g., using the probe tips show in previous figures). The device under test 312 may include copper traces 1004 on both sides of the transistor circuitry soldered 1008 to a circuit board 1010. In certain conditions, a thin electron absorptive layer 1012 may be added to the surface of the device under test 312 to aid the heating while preventing device damage. To measure device changes, one method is to monitor the current change of the device under test 312. To do this, a small bias may be applied across the device under test 312, and then a map of that current value may be made as the electron beam scans. In the area of a defect, a change in the current flowing through the device under test 312 may be observed. The other method is to “loop” a test pattern into the device under test 312 that is then scored as a pass or a fail. By testing the device under test 312 at various voltages, the boundary where the device under test 312 fails may be identified. Operating the device under test 312 at the boundary voltage and then scanning the device under test 312 with a hot probe (e.g., as shown in the techniques in FIGS. 1-9) may allow for mapping the pass/fail condition at each pixel of the scan. Defective areas will lead to a higher passing or failing rate relative to the non-defective area.

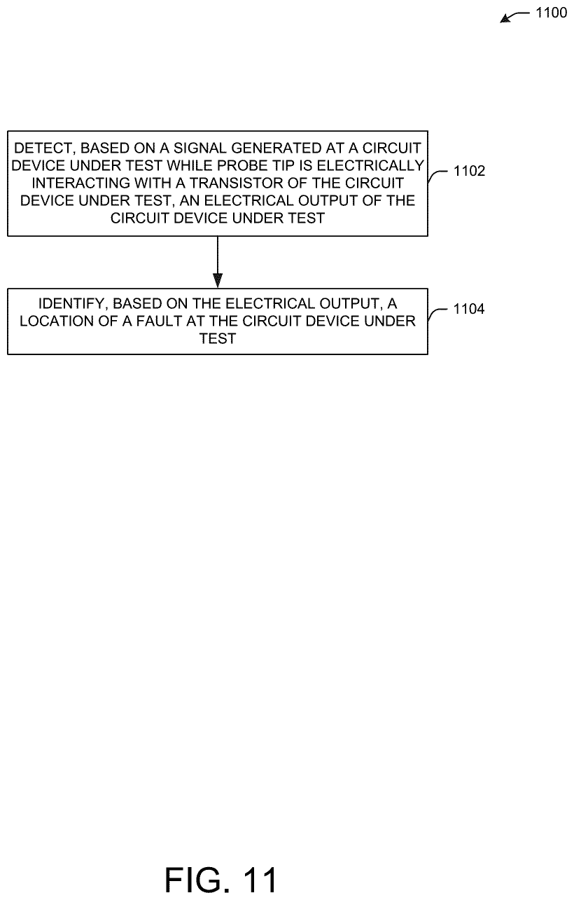

FIG. 11 illustrates a flow diagram of an illustrative process 1100 for using an electron beam probe tip for testing a circuit device, in accordance with one or more example embodiments of the present disclosure.

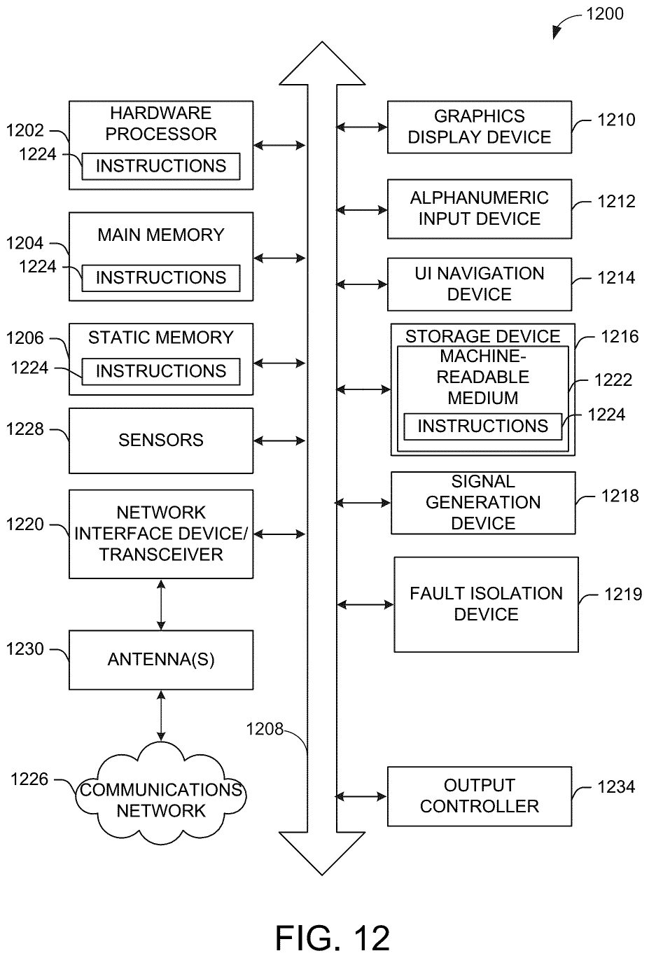

At block 1102, a device (the fault detection device 1219 of FIG. 12) may detect, based on a signal generated at a circuit device under test while a probe tip is in contact with or otherwise electrically interacting with (e.g., from some non-zero distance) a transistor (e.g., conductive surface) of the circuit device under test, an electrical output of the circuit device under test. The signal generation and detection may use any of the techniques described herein, including those shown and described in FIGS. 3-10.

At block 1104, the device may identify, based on the electrical output, a location of the fault. The fault detection and location identification may be based on any of the techniques described herein, including those shown and described in FIGS. 3-10.

It is understood that the above descriptions are for purposes of illustration and are not meant to be limiting.

FIG. 12 depicts a block diagram of an example machine 1200 upon which any of one or more techniques (e.g., methods) may be performed, in accordance with one or more example embodiments of the present disclosure.

In other embodiments, the machine 1200 may operate as a stand-alone device or may be connected (e.g., networked) to other machines. Further, while only a single machine is illustrated, the term “machine” shall also be taken to include any collection of machines that individually or jointly execute a set (or multiple sets) of instructions to perform any one or more of the methodologies discussed herein. For example, the machine 1200 may include or represent components of the IC testing tools shown/described herein.

Examples, as described herein, may include or may operate on logic or a number of components, modules, or mechanisms. Modules are tangible entities (e.g., hardware) capable of performing specified operations when operating. A module includes hardware. In an example, the hardware may be specifically configured to carry out a specific operation (e.g., hardwired). In another example, the hardware may include configurable execution units (e.g., transistors, circuits, etc.) and a computer-readable medium containing instructions where the instructions configure the execution units to carry out a specific operation when in operation. The configuring may occur under the direction of the execution units or a loading mechanism. Accordingly, the execution units are communicatively coupled to the computer-readable medium when the device is operating. In this example, the execution units may be a member of more than one module. For example, under operation, the execution units may be configured by a first set of instructions to implement a first module at one point in time and reconfigured by a second set of instructions to implement a second module at a second point in time.

Certain embodiments may be implemented in one or a combination of hardware, firmware, and software. Other embodiments may also be implemented as program code or instructions stored on a computer-readable storage device, which may be read and executed by at least one processor to perform the operations described herein. A computer-readable storage device may include any non-transitory memory mechanism for storing information in a form readable by a machine (e.g., a computer). For example, a computer-readable storage device may include read-only memory (ROM), random-access memory (RAM), magnetic disk storage media, optical storage media, flash-memory devices, and other storage devices and media. In some embodiments, the machine 1200 may include one or more processors and may be configured with program code instructions stored on a computer-readable storage device memory. Program code and/or executable instructions embodied on a computer-readable medium may be transmitted using any appropriate medium including, but not limited to, wireless, wireline, optical fiber cable, RF, etc., or any suitable combination of the foregoing. Program code and/or executable instructions for carrying out operations for aspects of the disclosure may be written in any combination of one or more programming languages, including an object-oriented programming language such as Java, Smalltalk, C++ or the like, and conventional procedural programming languages, such as the “C” programming language or similar programming languages. The program code and/or executable instructions may execute entirely on a device, partly on the device, as a stand-alone software package, partly on the device and partly on a remote device or entirely on the remote device or server.

The machine 1200 may include at least one hardware processor 1202 (e.g., a central processing unit (CPU), a graphics processing unit (GPU), a hardware processor core, or any combination thereof), a main memory 1204, and a static memory 1206. The machine 1200 may include drive circuitry 1218. The machine 1200 may further include a graphics display device 1210, an alphanumeric input device 1212 (e.g., a keyboard), and a user interface (UI) navigation device 1214 (e.g., a mouse). In an example, the graphics display device 1210, the alphanumeric input device 1212, and the UI navigation device 1214 may be a touch screen display. The machine 1200 may additionally include a storage device 1216, a signal generation device 1218, a fault isolation device 1219 (e.g., capable of controlling the fault testing devices herein, and/or analyzing the data provided by the fault testing devices herein), a network interface device/transceiver 1220 coupled to antenna(s) 1230, and one or more sensors 1228. The machine 1200 may include an output controller 1234, such as a serial (e.g., universal serial bus (USB), parallel, or other wired or wireless (e.g., infrared (IR), near field communication (NFC), etc.) connection to communicate with or control one or more peripheral devices. These components may couple and may communicate with each other through an interlink (e.g., bus) 1208. Further, the machine 1200 may include a power supply device that is capable of supplying power to the various components of the machine 1200.

The storage device 1216 may include a machine-readable medium 1222 on which is stored one or more sets of data structures or instructions 1224 (e.g., software) embodying or utilized by any one or more of the techniques or functions described herein. The instructions 1224 may also reside, completely or at least partially, within the main memory 1204, within the static memory 1206, or within the hardware processor 1202 during execution thereof by the machine 1200. In an example, one or any combination of the hardware processor 1202, the main memory 1204, the static memory 1206, or the storage device 1216 may constitute machine-readable media.

The antenna(s) 1230 may include one or more directional or omnidirectional antennas, including, for example, dipole antennas, monopole antennas, patch antennas, loop antennas, microstrip antennas, or other types of antennas suitable for the transmission of RF signals. In some embodiments, instead of two or more antennas, a single antenna with multiple apertures may be used. In these embodiments, each aperture may be considered a separate antenna. In some multiple-input multiple-output (MIMO) embodiments, the antennas may be effectively separated for spatial diversity and the different channel characteristics that may result between each of the antennas and the antennas of a transmitting station.

The fault isolation device 1219 may carry out or perform any of the operations and processes (e.g., the process 1100) described and shown above.

It is understood that the above are only a subset of what the fault isolation device 1219 may be configured to perform and that other functions included throughout this disclosure may also be performed by the fault isolation device 1219.

While the machine-readable medium 1222 is illustrated as a single medium, the term “machine-readable medium” may include a single medium or multiple media (e.g., a centralized or distributed database, and/or associated caches and servers) configured to store the one or more instructions 1224.

Various embodiments may be implemented fully or partially in software and/or firmware. This software and/or firmware may take the form of instructions contained in or on a non-transitory computer-readable storage medium. Those instructions may then be read and executed by one or more processors to enable performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM), random-access memory (RAM), magnetic disk storage media; optical storage media' a flash memory, etc.

The term “machine-readable medium” may include any medium that is capable of storing, encoding, or carrying instructions for execution by the robotic machine 1200 and that cause the robotic machine 1200 to perform any one or more of the techniques of the present disclosure, or that is capable of storing, encoding, or carrying data structures used by or associated with such instructions. Non-limiting machine-readable medium examples may include solid-state memories and optical and magnetic media. In an example, a massed machine-readable medium includes a machine-readable medium with a plurality of particles having resting mass. Specific examples of massed machine-readable media may include non-volatile memory, such as semiconductor memory devices (e.g., electrically programmable read-only memory (EPROM), or electrically erasable programmable read-only memory (EEPROM)) and flash memory devices; magnetic disks, such as internal hard disks and removable disks; magneto-optical disks; and CD-ROM and DVD-ROM disks.

The instructions 1224 may further be transmitted or received over a communications network 1226 using a transmission medium via the network interface device/transceiver 1220 utilizing any one of a number of transfer protocols (e.g., frame relay, internet protocol (IP), transmission control protocol (TCP), user datagram protocol (UDP), hypertext transfer protocol (HTTP), etc.). Example communications networks may include a local area network (LAN), a wide area network (WAN), a packet data network (e.g., the Internet), mobile telephone networks (e.g., cellular networks), plain old telephone (POTS) networks, wireless data networks (e.g., Institute of Electrical and Electronics Engineers (IEEE) 802.11 family of standards known as Wi-Fi®, and peer-to-peer (P2P) networks, among others. In an example, the network interface device/transceiver 1220 may include one or more physical jacks (e.g., Ethernet, coaxial, or phone jacks) or one or more antennas (e.g., antennas 1230) to connect to the communications network 1226. In an example, the network interface device/transceiver 1220 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the robotic machine 1200 and includes digital or analog communications signals or other intangible media to facilitate communication of such software. The operations and processes described and shown above may be carried out or performed in any suitable order as desired in various implementations. Additionally, in certain implementations, at least a portion of the operations may be carried out in parallel. Furthermore, in certain implementations, less than or more than the operations described may be performed.

Some examples may be described using the expression “in one example” or “an example” along with their derivatives. These terms mean that a particular feature, structure, or characteristic described in connection with the example is included in at least one example. The appearances of the phrase “in one example” in various places in the specification are not necessarily all referring to the same example.

Some examples may be described using the expression “coupled” and “connected” along with their derivatives. These terms are not necessarily intended as synonyms for each other. For example, descriptions using the terms “connected” and/or “coupled” may indicate that two or more elements are in direct physical or electrical contact with each other. The term “coupled,” however, may also mean that two or more elements are not in direct contact with each other, yet still co-operate or interact with each other.

In addition, in the foregoing Detailed Description, various features are grouped together in a single example to streamline the disclosure. This method of disclosure is not to be interpreted as reflecting an intention that the claimed examples require more features than are expressly recited in each claim. Rather, as the following claims reflect, the inventive subject matter lies in less than all features of a single disclosed example. Thus, the following claims are hereby incorporated into the Detailed Description, with each claim standing on its own as a separate example. In the appended claims, the terms “including” and “in which” are used as the plain-English equivalents of the respective terms “comprising” and “wherein,” respectively. Moreover, the terms “first,” “second,” “third,” and so forth, are used merely as labels and are not intended to impose numerical requirements on their objects.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

A data processing system suitable for storing and/or executing program code will include at least one processor coupled directly or indirectly to memory elements through a system bus. The memory elements can include local memory employed during actual execution of the program code, bulk storage, and cache memories that provide temporary storage of at least some program code to reduce the number of times code must be retrieved from bulk storage during execution. The term “code” covers a broad range of software components and constructs, including applications, drivers, processes, routines, methods, modules, firmware, microcode, and subprograms. Thus, the term “code” may be used to refer to any collection of instructions that, when executed by a processing system, perform a desired operation or operations.

Logic circuitry, devices, and interfaces herein described may perform functions implemented in hardware and implemented with code executed on one or more processors. Logic circuitry refers to the hardware or the hardware and code that implements one or more logical functions. Circuitry is hardware and may refer to one or more circuits. Each circuit may perform a particular function. A circuit of the circuitry may comprise discrete electrical components interconnected with one or more conductors, an integrated circuit, a chip package, a chipset, memory, or the like. Integrated circuits include circuits created on a substrate such as a silicon wafer and may comprise components. Integrated circuits, processor packages, chip packages, and chipsets may comprise one or more processors.

Processors may receive signals such as instructions and/or data at the input(s) and process the signals to generate at least one output. While executing code, the code changes the physical states and characteristics of transistors that make up a processor pipeline. The physical states of the transistors translate into logical bits of ones and zeros stored in registers within the processor. The processor can transfer the physical states of the transistors into registers and transfer the physical states of the transistors to another storage medium.

A processor may comprise circuits to perform one or more sub-functions implemented to perform the overall function of the processor. One example of a processor is a state machine or an application-specific integrated circuit (ASIC) that includes at least one input and at least one output. A state machine may manipulate the at least one input to generate the at least one output by performing a predetermined series of serial and/or parallel manipulations or transformations on the at least one input.

The logic as described above may be part of the design for an integrated circuit chip. The chip design is created in a graphical computer programming language, and stored in a computer storage medium or data storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication.

The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher-level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a processor board, a server platform, or a motherboard, or (b) an end product.

The word “exemplary” is used herein to mean “serving as an example, instance, or illustration.” Any embodiment described herein as “exemplary” is not necessarily to be construed as preferred or advantageous over other embodiments. The terms “computing device,” “user device,” “communication station,” “station,” “handheld device,” “mobile device,” “wireless device” and “user equipment” (UE) as used herein refers to a wireless communication device such as a cellular telephone, a smartphone, a tablet, a netbook, a wireless terminal, a laptop computer, a femtocell, a high data rate (HDR) subscriber station, an access point, a printer, a point of sale device, an access terminal, or other personal communication system (PCS) device. The device may be either mobile or stationary.

As used within this document, the term “communicate” is intended to include transmitting, or receiving, or both transmitting and receiving. This may be particularly useful in claims when describing the organization of data that is being transmitted by one device and received by another, but only the functionality of one of those devices is required to infringe the claim. Similarly, the bidirectional exchange of data between two devices (both devices transmit and receive during the exchange) may be described as “communicating,” when only the functionality of one of those devices is being claimed. The term “communicating” as used herein with respect to a wireless communication signal includes transmitting the wireless communication signal and/or receiving the wireless communication signal. For example, a wireless communication unit, which is capable of communicating a wireless communication signal, may include a wireless transmitter to transmit the wireless communication signal to at least one other wireless communication unit, and/or a wireless communication receiver to receive the wireless communication signal from at least one other wireless communication unit.

As used herein, unless otherwise specified, the use of the ordinal adjectives “first,” “second,” “third,” etc., to describe a common object, merely indicates that different instances of like objects are being referred to and are not intended to imply that the objects so described must be in a given sequence, either temporally, spatially, in ranking, or in any other manner.

Some embodiments may be used in conjunction with various devices and systems, for example, a personal computer (PC), a desktop computer, a mobile computer, a laptop computer, a notebook computer, a tablet computer, a server computer, a handheld computer, a handheld device, a personal digital assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wireless access point (AP), a wired or wireless router, a wired or wireless modem, a video device, an audio device, an audio-video (A/V) device, a wired or wireless network, a wireless area network, a wireless video area network (WVAN), a local area network (LAN), a wireless LAN (WLAN), a personal area network (PAN), a wireless PAN (WPAN), and the like.

Some embodiments may be used in conjunction with one way and/or two-way radio communication systems, cellular radio-telephone communication systems, a mobile phone, a cellular telephone, a wireless telephone, a personal communication system (PCS) device, a PDA device which incorporates a wireless communication device, a mobile or portable global positioning system (GPS) device, a device which incorporates a GPS receiver or transceiver or chip, a device which incorporates an RFID element or chip, a multiple input multiple output (MIMO) transceiver or device, a single input multiple output (SIMO) transceiver or device, a multiple input single output (MISO) transceiver or device, a device having one or more internal antennas and/or external antennas, digital video broadcast (DVB) devices or systems, multi-standard radio devices or systems, a wired or wireless handheld device, e.g., a smartphone, a wireless application protocol (WAP) device, or the like.

Some embodiments may be used in conjunction with one or more types of wireless communication signals and/or systems following one or more wireless communication protocols, for example, radio frequency (RF), infrared (IR), frequency-division multiplexing (FDM), orthogonal FDM (OFDM), time-division multiplexing (TDM), time-division multiple access (TDMA), extended TDMA (E-TDMA), general packet radio service (GPRS), extended GPRS, code-division multiple access (CDMA), wideband CDMA (WCDMA), CDMA 2000, single-carrier CDMA, multi-carrier CDMA, multi-carrier modulation (MDM), discrete multi-tone (DMT), Bluetooth®, global positioning system (GPS), Wi-Fi, Wi-Max, ZigBee, ultra-wideband (UWB), global system for mobile communications (GSM), 2G, 2.5G, 3G, 3.5G, 4G, fifth generation (5G) mobile networks, 3GPP, long term evolution (LTE), LTE advanced, enhanced data rates for GSM Evolution (EDGE), or the like. Other embodiments may be used in various other devices, systems, and/or networks.

The following examples pertain to further embodiments.

Example 1 may include a method for fault isolation in integrated circuits using one or more probe tips, the method comprising: generating a signal at a circuit device under test while a probe tip electrically interacts with a transistor or wire of the circuit device under test; detecting, based on the signal, an electrical output of the circuit device under test; and identifying, based on the electrical output, a location of a fault in or around the circuit device under test.

Example 2 may include the method of example 1 and/or any other example herein, wherein the probe tip is connected to an electron beam (e-beam probe).

Example 3 may include the method of example 1 and/or any other example herein, wherein generating the signal is performed by the probe tip while the probe tip is in contact with the circuit device under test at or near a transistor.

Example 4 may include the method of example 1 and/or any other example herein, wherein detecting the electrical output is performed by the probe tip while the probe tip is in contact with the circuit device under test at or near the transistor.

Example 5 may include the method of example 1 and/or any other example herein, further comprising heating, using the probe tip, the circuit device under test.

Example 6 may include the method of example 1 and/or any other example herein, wherein identifying the fault location is based on a nanoprobing technique of e-beam induced current (EBIC), e-beam absorbed current (EBAC), or e-beam induced resistance change (EBIRCh).

Example 7 may include the method of example 1 and/or any other example herein, wherein identifying the fault location is based on a thermal sensor of the probe tip or on a magnetic sensor of the probe tip.

Example 8 may include the method of example 1 and/or any other example herein, wherein identifying the location is based on a near-field fault isolation technique of laser assisted device alternation (LADA) or thermal assisted device alteration (TADA).

Example 9 may include the method of example 1 and/or any other example herein, wherein the fault is an electrical open, and wherein identifying the location is based on a frequency enhanced electro force microscopy (FE-EFM) technique.

Example 10 may include the method of example 1 and/or any other example herein, wherein the fault is an electrical open, and wherein identifying the location is based on a lock-in conductive atomic force microscopy (LI-CAFM) technique.

Example 11 may include the method of example 1 and/or any other example herein, wherein the fault is an electrical short, and wherein identifying the location is based on a frequency enhanced magnetic force microscopy (FE-MFM) technique.

Example 12 may include the method of example 1 and/or any other example herein, wherein the fault is an electrical short, and wherein identifying the location is based on a lock-in scanning thermal microscopy (LI-SThM) technique.

Example 13 may include the method of example 1 and/or any other example herein, wherein identifying the location is based on a combination of an EFM and MFM technique.

Example 14 may include the method of example 1 and/or any other example herein, wherein identifying the location is based on a scanning joule expansion microscopy for fault isolation (SJEM4FI) technique.

Example 15 may include a device for fault isolation in integrated circuits using a probe tip, the device configured to: detect, based on a signal generated at a circuit device under test while a probe tip is electrically interacts with the circuit device under test, an electrical output of the circuit device under test; and identify, based on the electrical output, a location of a fault at the circuit device under test.

Example 16 may include the device of example 15 and/or any other example herein, wherein the probe is connected to an electron beam (e-beam) probe.

Example 17 may include the device of example 15 and/or any other example herein, wherein to identify the location is based on a nanoprobing technique of e-beam induced current (EBIC), e-beam absorbed current (EBAC), or e-beam induced resistance change (EBIRCh).

Example 18 may include the device of example 15 and/or any other example herein, wherein to identify the location is based on a thermal sensor of the probe tip or on a magnetic sensor of the probe tip.

Example 19 may include the device of example 15 and/or any other example herein, wherein to identify the location is based on a near-field fault isolation technique of laser assisted device alternation (LADA) or thermal assisted device alteration (TADA).

Example 20 may include a system for fault isolation in integrated circuits using a probe tip, the system comprising: a probe comprising a probe tip; and memory coupled to at least one processor, the at least one processor configured to: detect, based on a signal generated at a circuit device under test while the probe tip electrically interacts with the circuit device under test, an electrical output of the circuit device under test; and identify, based on the electrical output, a location of a fault at the circuit device under test.

Embodiments according to the disclosure are in particular disclosed in the attached claims directed to a method, a storage medium, a device and a computer program product, wherein any feature mentioned in one claim category, e.g., method, can be claimed in another claim category, e.g., system, as well. The dependencies or references back in the attached claims are chosen for formal reasons only. However, any subject matter resulting from a deliberate reference back to any previous claims (in particular multiple dependencies) can be claimed as well, so that any combination of claims and the features thereof are disclosed and can be claimed regardless of the dependencies chosen in the attached claims. The subject-matter which can be claimed comprises not only the combinations of features as set out in the attached claims but also any other combination of features in the claims, wherein each feature mentioned in the claims can be combined with any other feature or combination of other features in the claims. Furthermore, any of the embodiments and features described or depicted herein can be claimed in a separate claim and/or in any combination with any embodiment or feature described or depicted herein or with any of the features of the attached claims.

The foregoing description of one or more implementations provides illustration and description, but is not intended to be exhaustive or to limit the scope of embodiments to the precise form disclosed. Modifications and variations are possible in light of the above teachings or may be acquired from practice of various embodiments.

Certain aspects of the disclosure are described above with reference to block and flow diagrams of systems, methods, apparatuses, and/or computer program products according to various implementations. It will be understood that one or more blocks of the block diagrams and flow diagrams, and combinations of blocks in the block diagrams and the flow diagrams, respectively, may be implemented by computer-executable program instructions. Likewise, some blocks of the block diagrams and flow diagrams may not necessarily need to be performed in the order presented, or may not necessarily need to be performed at all, according to some implementations.

These computer-executable program instructions may be loaded onto a special-purpose computer or other particular machine, a processor, or other programmable data processing apparatus to produce a particular machine, such that the instructions that execute on the computer, processor, or other programmable data processing apparatus create means for implementing one or more functions specified in the flow diagram block or blocks. These computer program instructions may also be stored in a computer-readable storage media or memory that may direct a computer or other programmable data processing apparatus to function in a particular manner, such that the instructions stored in the computer-readable storage media produce an article of manufacture including instruction means that implement one or more functions specified in the flow diagram block or blocks. As an example, certain implementations may provide for a computer program product, comprising a computer-readable storage medium having a computer-readable program code or program instructions implemented therein, said computer-readable program code adapted to be executed to implement one or more functions specified in the flow diagram block or blocks. The computer program instructions may also be loaded onto a computer or other programmable data processing apparatus to cause a series of operational elements or steps to be performed on the computer or other programmable apparatus to produce a computer-implemented process such that the instructions that execute on the computer or other programmable apparatus provide elements or steps for implementing the functions specified in the flow diagram block or blocks.

Accordingly, blocks of the block diagrams and flow diagrams support combinations of means for performing the specified functions, combinations of elements or steps for performing the specified functions and program instruction means for performing the specified functions. It will also be understood that each block of the block diagrams and flow diagrams, and combinations of blocks in the block diagrams and flow diagrams, may be implemented by special-purpose, hardware-based computer systems that perform the specified functions, elements or steps, or combinations of special-purpose hardware and computer instructions.

Conditional language, such as, among others, “can,” “could,” “might,” or “may,” unless specifically stated otherwise, or otherwise understood within the context as used, is generally intended to convey that certain implementations could include, while other implementations do not include, certain features, elements, and/or operations. Thus, such conditional language is not generally intended to imply that features, elements, and/or operations are in any way required for one or more implementations or that one or more implementations necessarily include logic for deciding, with or without user input or prompting, whether these features, elements, and/or operations are included or are to be performed in any particular implementation.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims. Although specific terms are employed herein, they are used in a generic and descriptive sense only and not for purposes of limitation.

What is claimed is:

1. A method for fault isolation in integrated circuits using one or more probe tips, the method comprising:
generating a signal at a circuit device under test while a probe tip electrically interacts with a transistor or wire of the circuit device under test;
detecting, based on the signal, an electrical output of the circuit device under test; and
identifying, based on the electrical output, a location of a fault in or around the circuit device under test.

2. The method of claim 1, wherein the probe tip is connected to an electron beam (e-beam probe).

3. The method of claim 1, wherein generating the signal is performed by the probe tip while the probe tip is in contact with the circuit device under test at or near a transistor.

4. The method of claim 1, wherein detecting the electrical output is performed by the probe tip while the probe tip is in contact with the circuit device under test at or near the transistor.

5. The method of claim 1, further comprising heating, using the probe tip, the circuit device under test.

6. The method of claim 1, wherein identifying the fault location is based on a nanoprobing technique of e-beam induced current (EBIC), e-beam absorbed current (EBAC), or e-beam induced resistance change (EBIRCh).

7. The method of claim 1, wherein identifying the fault location is based on a thermal sensor of the probe tip or on a magnetic sensor of the probe tip.

8. The method of claim 1, wherein identifying the location is based on a near-field fault isolation technique of laser assisted device alternation (LADA) or thermal assisted device alteration (TADA).

9. The method of claim 1, wherein the fault is an electrical open, and wherein identifying the location is based on a frequency enhanced electro force microscopy (FE-EFM) technique.

10. The method of claim 1, wherein the fault is an electrical open, and wherein identifying the location is based on a lock-in conductive atomic force microscopy (LI-CAFM) technique.

11. The method of claim 1, wherein the fault is an electrical short, and wherein identifying the location is based on a frequency enhanced magnetic force microscopy (FE-MFM) technique.

12. The method of claim 1, wherein the fault is an electrical short, and wherein identifying the location is based on a lock-in scanning thermal microscopy (LI-SThM) technique.

13. The method of claim 1, wherein identifying the location is based on a combination of an EFM and MFM technique.

14. The method of claim 1, wherein identifying the location is based on a scanning joule expansion microscopy for fault isolation (SJEM4FI) technique.

15. A device for fault isolation in integrated circuits using a probe tip, the device configured to:
detect, based on a signal generated at a circuit device under test while a probe tip is electrically interacts with the circuit device under test, an electrical output of the circuit device under test; and
identify, based on the electrical output, a location of a fault at the circuit device under test.

16. The device of claim 15, wherein the probe is connected to an electron beam (e-beam) probe.

17. The device of claim 15, wherein to identify the location is based on a nanoprobing technique of e-beam induced current (EBIC), e-beam absorbed current (EBAC), or e-beam induced resistance change (EBIRCh).

18. The device of claim 15, wherein to identify the location is based on a thermal sensor of the probe tip or on a magnetic sensor of the probe tip.

19. The device of claim 15, wherein to identify the location is based on a near-field fault isolation technique of laser assisted device alternation (LADA) or thermal assisted device alteration (TADA).

20. A system for fault isolation in integrated circuits using a probe tip, the system comprising:
a probe comprising a probe tip; and
memory coupled to at least one processor, the at least one processor configured to:
detect, based on a signal generated at a circuit device under test while the probe tip electrically interacts with the circuit device under test, an electrical output of the circuit device under test; and
identify, based on the electrical output, a location of a fault at the circuit device under test.
